(19) United States
(12) Patent Application Publication
(10) Pub. No.: US 2009/0021317 A1
(43) Pub. Date: Jan. 22, 2009

(54) CMOS cross-coupled differential voltage controlled oscillator

(75) Inventor: Ming-Hung Hsieh, Lujhou City (TW)

Correspondence Address: BACON & THOMAS, PLLC, 625 SLATERS LANE, FOURTH FLOOR, ALEXANDRIA, VA, 22314-1176, US

(73) Assignee: UNIBAND ELECTRONIC CORP., Hsinchu (TW)

(21) Appl. No.: 12/078,075

(22) Filed: Mar. 27, 2008

(30) Foreign Application Priority Data
Jul. 19, 2007 (TW) 096126292

(51) Int. Cl. H03B 5/12; H03B 5/18

(52) U.S. Cl. 331/117 FE

(57) ABSTRACT

A CMOS cross-coupled differential voltage controlled oscillator is provided with a pair of oscillator outputs. The oscillator includes a current control unit, a first cross-coupled differential pair, an inductor unit, a capacitor unit, a second cross-coupled differential pair and a voltage controller. The current control unit is coupled between a relatively-high voltage and a relatively-low voltage. The first cross-coupled differential pair, the inductor unit, the capacitor unit and the second cross-coupled differential pair are coupled between the pair of oscillator outputs. According to the present invention, the inductor unit is provided with a midway node. The voltage controller is coupled and powered by the midway node.

### BACKGROUND OF THE INVENTION

1. Field of the Invention

The present invention relates to a voltage controlled oscillator. More particular, the present invention relates to a CMOS cross-coupled differential voltage controlled oscillator.

2. Description of Prior Art

FIG. 1 shows a circuit diagram of a conventional voltage controlled oscillator 1. Refer to FIG. 1, the conventional voltage controlled oscillator 1 comprises a current control unit 11, a PMOS cross-coupled differential pair 12, an inductor unit 13, a capacitor unit 14, a NMOS cross-coupled differential pair 15, and a voltage control unit 16. Because the required capacitance values under different operating frequency vary, the on/off status of varactor SWCAP1, SWCAP2, SWCAP3, SWCAP4 of the capacitor unit 14 is adjusted to generate the corresponding capacitance. The voltage control unit 16 is powered by VDD and GND. When a varactor is off, the potentials at two ends of the varactor are different. The different potentials increase the OFF capacitance C_{OFF} of the varactor, which shortens the tuning range between C_{ON}, the ON capacitance of the varactor and C_{OFF}. In addition, different flicker noises from VDD and oscillator outputs VCOP/VCON generate an AM-to-PM noise so as to increase phase noise and thus have critical impact on the frequency accuracy.

### SUMMARY OF THE INVENTION

Therefore, an objective of the present invention is to provide a CMOS cross-coupled differential voltage controlled oscillator which can lower the OFF capacitance value of a varactor for improving the tuning range between the ON capacitance and OFF capacitance thereof.

The other objective of the present invention is to provide a CMOS cross-coupled differential voltage controlled oscillator which can generate the same flicker noise at two ends of a varactor such that phase noise can be eliminated.

Another objective of the present invention is to provide a CMOS cross-coupled differential voltage controlled oscillator which can filter 2^{nd} harmonic of a shared node in an inductor unit.

In order to achieve the above objectives, the present invention provides a cross-coupled differential voltage controlled oscillator. The oscillator includes a current control unit, a first cross-coupled differential pair, an inductor unit, a capacitor unit, a second cross-coupled differential pair and a voltage control unit. The current control unit is coupled between a relatively-high voltage and a relatively-low voltage. The first cross-coupled differential pair, the inductor unit, the capacitor unit and the second cross-coupled differential pair are coupled between the pair of oscillator outputs and cascaded between the current control unit and relatively-high voltage. The inductor unit further includes a shared node. The voltage control unit is coupled between the shared node and the relatively-low voltage. The voltage control unit controls the capacitor unit according to a plurality of voltage control signals and then outputs signals to the pair of oscillator outputs.

Moreover, in order to achieve the above objectives, the present invention further provides another cross-coupled differential voltage controlled oscillator. The oscillator includes a current control unit, a first cross-coupled differential pair, an inductor unit, a capacitor unit, a second cross-coupled differential pair and a voltage control unit. The current control unit is coupled between a relatively-high voltage and a relatively-low voltage. The first cross-coupled differential pair, the inductor unit, the capacitor unit and the second cross-coupled differential pair are coupled between the pair of oscillator outputs and cascaded between the current control unit and relatively-low voltage. The inductor unit further includes a shared node. The voltage control unit is coupled between the shared node and the relatively-high voltage. The voltage control unit controls said capacitor unit according to a plurality of voltage control signals and then outputs signals to the pair of oscillator outputs.

### BRIEF DESCRIPTION OF THE DRAWINGS

FIG. 1 shows a prior art voltage controlled oscillator;

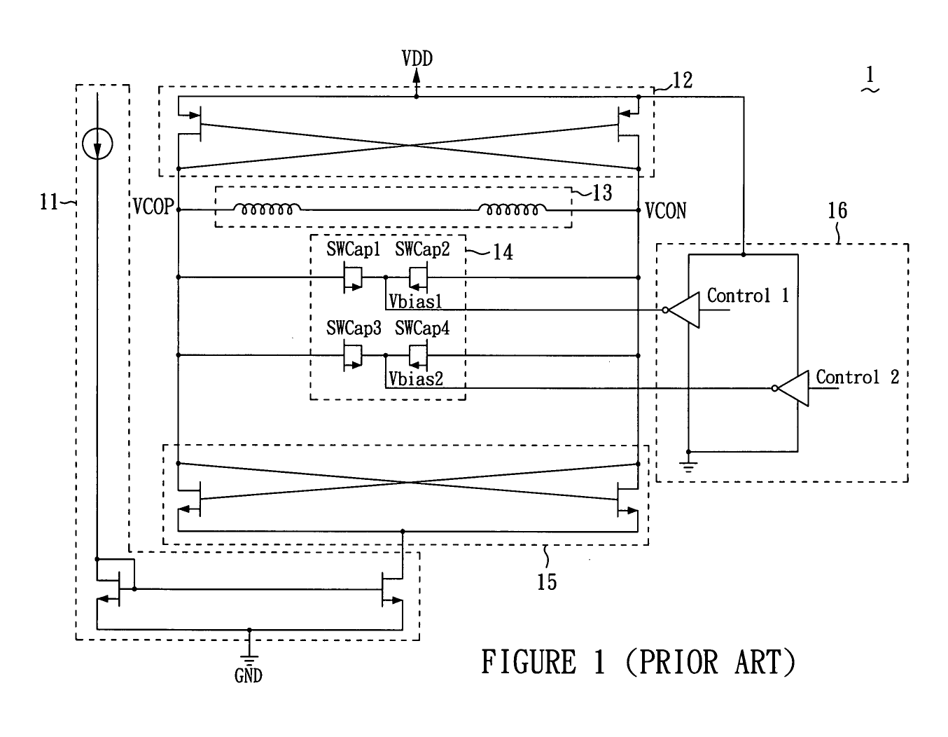

FIG. 2 shows the circuit diagram of a voltage controlled oscillator of a preferred embodiment;

FIG. 3 shows the circuit diagram of a voltage controlled oscillator of another preferred embodiment;

FIG. 4 shows the circuit diagram of a voltage controlled oscillator of further another preferred embodiment; and

FIG. 5 shows the circuit diagram of a voltage controlled oscillator of still another preferred embodiment.

### DETAILED DESCRIPTION OF THE PREFERRED EMBODIMENTS

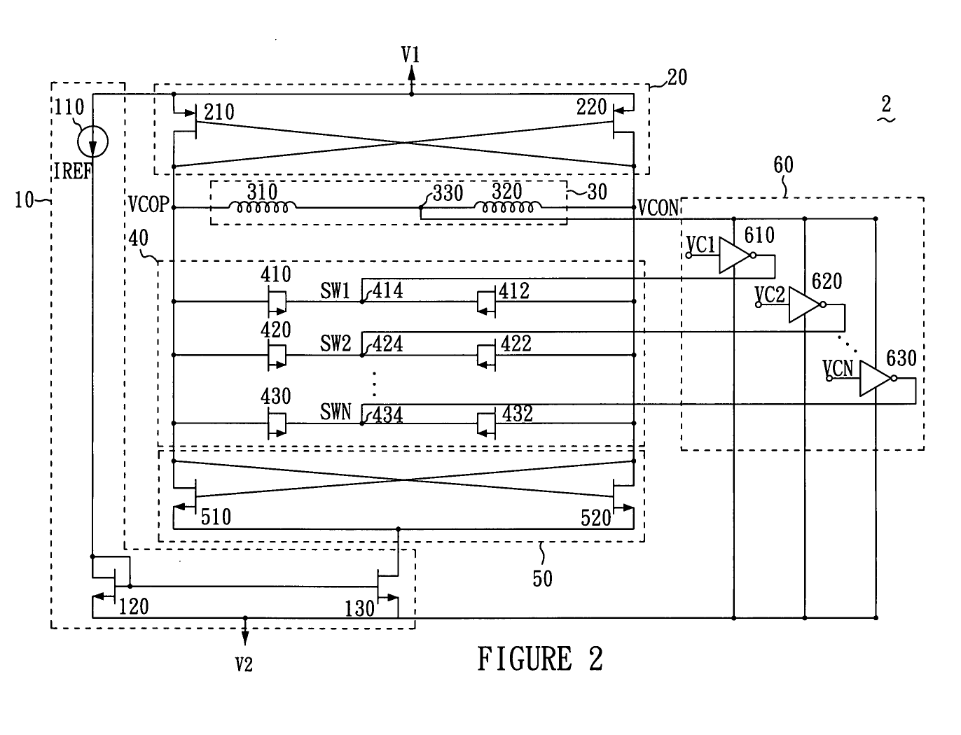

FIG. 2 shows a circuit diagram of a voltage controlled oscillator 2 of a preferred embodiment in accordance with the present invention. As shown in FIG. 2, the voltage controlled oscillator 2 includes power voltages V1 and V2, a current control unit 10, a first cross-coupled differential pair 20, an inductor unit 30, a capacitor unit 40, a second cross-coupled differential pair 50, voltage control unit 60, a plurality of voltage control signals VC1, VC2 . . . VCN and oscillator outputs VCON and VCOP. According to the present invention, the power voltage V1 is higher than the power voltage V2. The combinations of V1 and V2 can be VDD and GND, VDD and −VDD, or GND and −VDD, where GND refers to ground voltage, VDD can be 5V, 3.3V, 2.5V, 1.8V. The combinations applied here are used as examples demonstrating preferred embodiment and the scope of the present invention is not limited to above combinations.

The current control unit 10 comprises a current source 110, two NMOS field effect transistors 120 and 130. The drain and the gate of the NMOS field effect transistor 120 are coupled to the gate of the NMOS field effect transistor 130. The sources of the NMOS field effect transistors 120 and 130 are coupled to the power voltage V2. The current source 110 is coupled between the power voltage V1 and the drain of the NMOS field effect transistor 120 to offer a reference current IREF such that the current control unit 10 forms a current mirror.

The first cross-coupled differential pair 20, the inductor unit 30, the capacitor unit 40, and the second cross-coupled differential pair 50 are cascaded between the power voltage V1 and the current control unit 10. The cross-coupled differential pair 20 includes two PMOS field effect transistors 210 and 220. The sources of the PMOS field effect transistors 210 and PMOS field effect transistor 220 are coupled to the power voltage V1. The gate of the PMOS field effect transistor 210 and the drain of the PMOS field effect transistor 220 are coupled to the oscillator output VCON The drain of the PMOS field effect transistor 210 and the gate of the PMOS field effect transistor 220 are coupled to the oscillator output VCOP.

The inductor unit 30 is coupled between the oscillator outputs VCON and VCOP. The inductor unit 30 further includes two inductors 310 and 320 coupled to a shared node 330. Alternatively, the inductor unit 30 can be implemented by single inductor, where shared node 330 is the location near the middle of the single inductor.

The capacitor unit 40 comprises a plurality of switch capacitor sets SW1, SW2 . . . SWN. The switch capacitor sets SW1, SW2 . . . SWN are parallel coupled between the oscillator outputs VCON and VCOP. As shown in FIG. 2, the switch capacitor set SW1 includes two varactors 410 and 412. The coupling node of the varactors 410 and 412 is a bias point 414. The switch capacitor set SW2 includes two varactors 420 and 422. The coupling node of the varactors 420 and 422 is a bias point 424. Respectively, the switch capacitor set SWN includes two varactors 430 and 432. The coupling node of the varactors 430 and 432 is bias point 434. For example, the varactors mentioned above can be implemented with junction varactors or MOS transistors.

The second cross-coupled differential pair 50 is coupled between the oscillator outputs VCON and VCOP. The second cross-coupled differential pair 50 is formed by NMOS field effect transistors 510 and 520. The sources of the NMOS field effect transistor 510 and NMOS field effect transistor 520 are coupled to the drain of the NMOS field effect transistor 130 of the current control unit 10. The gate of the NMOS field effect transistor 510 and the drain of the NMOS field effect transistor 520 are coupled to the oscillator output VCON. The drain of the NMOS field effect transistor 510 and the gate of the NMOS field effect transistor 520 are coupled to the oscillator output VCOP.

The voltage control unit 60 is coupled between the shared node 330 of the inductor unit 30 and power voltage V2. The voltage control unit 60 is powered by the shared node 330 of the inductor unit 30 and power voltage V2. The voltage control unit 60 has a plurality of inverters or buffers 610, 620 . . . 630, corresponding to voltage control signals VC1, VC2 . . . VCN, for inverting signal phase of the voltage control signals VC1, VC2 . . . VCN. The inverted control signals VC1, VC2 . . . VCN are coupled to the bias points 414, 424 . . . 434 of the switch capacitor sets SW1, SW2 . . . SWN to control over the switch capacitor sets, respectively. The voltage control unit 60 is powered by the shared node 330 and the power voltage V2 such that the inverters 610, 620 . . . 630 are also powered by the shared node 330 and the power voltage V2.

Different operating frequency requires different capacitance value controlled by the ON/OFF status of the varactors of the capacitor units SW1, SW2 . . . SWN. According to the present invention, when a varactor is OFF, the potentials at two ends of the varactor are about the same, which can increase tuning range between the ON capacitance C_{ON} and the OFF capacitance C_{OFF} thereof. In addition, the inverters 610, 620 . . . 630 are all coupled and powered by the shared node 330 of the inductor unit 30 such that flicker noise from the oscillator outputs VCOP and VCON are about the same so as to eliminate phase noise.

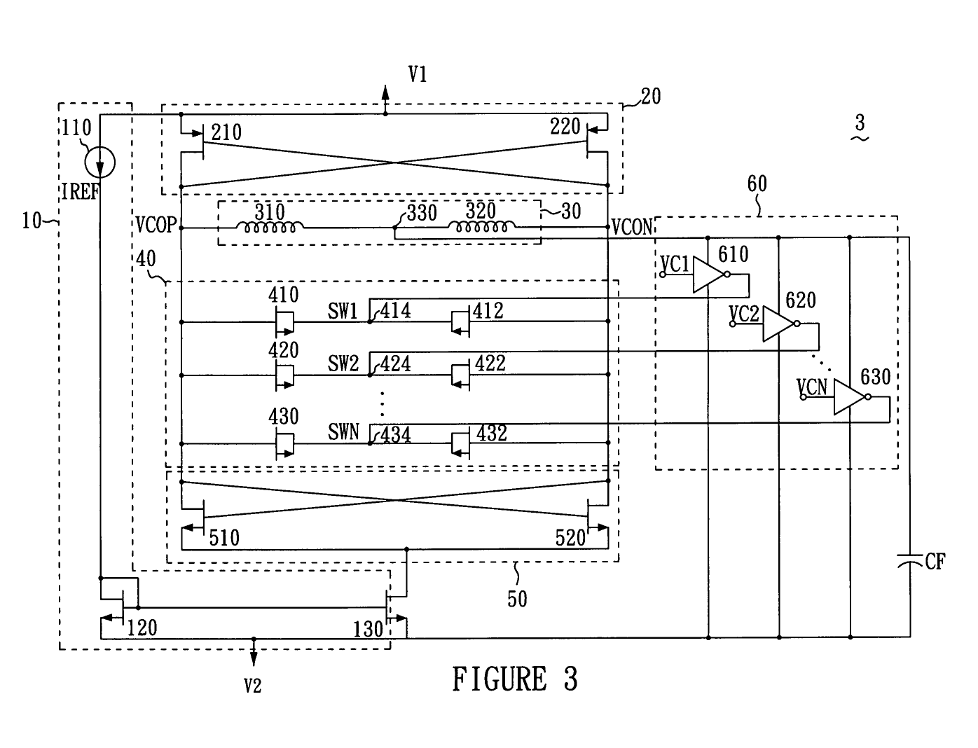

FIG. 3 shows another preferred embodiment of a voltage controlled oscillator 3 of the present invention. As compared with the embodiment shown in FIG. 2, a voltage controlled oscillator 3 further installed a capacitor CF between the shared node 330 of the inductor unit 30 and the power voltage V2. The signals going through the oscillator outputs VCOP and VCON are differential signals, which generates 2nd harmonic at the shared node 330 of the inductor unit 30. According to the present invention, the capacitor CF and the inductor unit 30 form a low pass filter for filtering the 2nd harmonic.

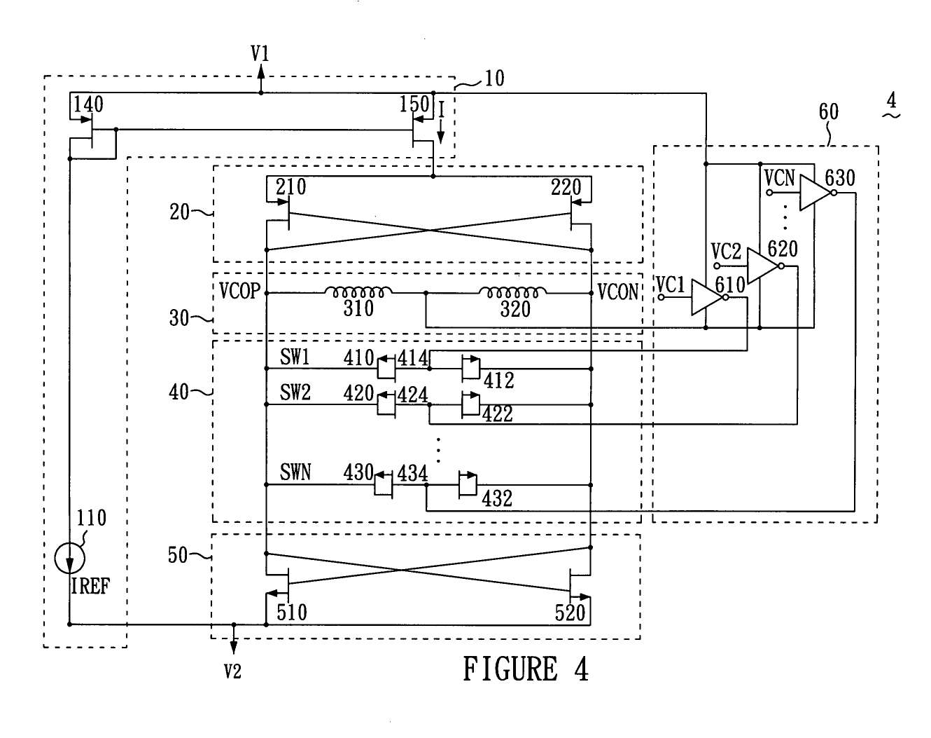

FIG. 4 shows a circuit diagram of a voltage controlled oscillator 4 of further another preferred embodiment. As shown in FIG. 4, the voltage controlled oscillator 4 includes power voltage V1 and V2, a current control unit 10, a first cross-coupled differential pair 20, an inductor unit 30, a capacitor unit 40, a second cross-coupled differential pair 50, voltage control unit 60, a plurality of voltage control signals VC1, VC2 . . . VCN and oscillator outputs VCON and VCOP. According to present invention, the power voltage V1 is higher than power voltage V2. The combinations of V1 and V2 can be VDD and GND, VDD and −VDD, or GND and −VDD, where GND refers to ground voltage, VDD can be 5V, 3.3V, 2.5V, 1.8V. The combinations applied here are used as examples demonstrating preferred embodiment and the scope of the present invention is not limited to above combinations.

The current control unit 10 comprises a current source 110, two PMOS field effect transistors 140 and 150. The drain and the gate of the PMOS field effect transistor 140 are coupled to the gate of the PMOS field effect transistor 150. The sources of the PMOS field effect transistors 140 and 150 are coupled to the power voltage V1. The current source 110 is coupled between the power voltage V2 and the drain of the PMOS field effect transistor 140 to offer a reference current IREF such that the current control unit 10 forms a current mirror.

The first cross-coupled differential pair 20, the inductor unit 30, the capacitor unit 40, and the second cross-coupled differential pair 50 are cascaded between the power voltage V2 and the current control unit 10. The cross-coupled differential pair 20 includes two PMOS field effect transistor 210 and 220. The source of the PMOS field effect transistor 210 and PMOS field effect transistor 220 are coupled to the drain of the PMOS field effect transistor 150 of the current unit control 10. The gate of the PMOS field effect transistor 210 and the drain of the PMOS field effect transistor 220 are coupled to the oscillator output VCON The drain of the PMOS field effect transistor 210 and the gate of the PMOS field effect transistor 220 are coupled to the oscillator output VCOP.

The inductor unit 30 is coupled between the oscillator outputs VCON and VCOP. The inductor unit 30 further includes two inductors 310 and 320 coupled to a shared node 330. Alternatively, the inductor unit 30 can be implemented by single inductor, where the shared node 330 is the location near the middle of the single inductor.

The capacitor unit 40 comprises a plurality of switch capacitor sets SW1, SW2 . . . SWN. The switch capacitor sets SW1, SW2 . . . SWN are parallel coupled between the oscillator outputs VCON and VCOP. As shown in FIG. 4, the switch capacitor set SW1 includes two varactors 410 and 412. The coupling node of the varactors 410 and 412 is a bias point 414. The switch capacitor set SW2 includes two varactors 420 and 422. The coupling node of the varactor 420 and 422 is a bias point 424. Respectively, the switch capacitor set SWN includes two varactors 430 and 432. The coupling node of the varactor 430 and 432 is bias point 434. The varactors mentioned above can be implemented with junction varactors or MOS transistors.

The second cross-coupled differential pair 50 is coupled between the oscillator outputs VCON and VCOP. The second cross-coupled differential pair 50 is formed by NMOS field effect transistor 510 and 520. The source of the NMOS field effect transistor 510 and NMOS field effect transistor 520 are coupled to the power voltage V2. The gate of the NMOS field effect transistor 510 and the drain of the NMOS field effect transistor 520 are coupled to the oscillator output VCON. The drain of the NMOS field effect transistor 510 and the gate of the NMOS field effect transistor 520 are coupled to the oscillator output VCOP.

The voltage control unit 60 is coupled between the shared node 330 of the inductor unit 30 and power voltage V1. The voltage control unit 60 is powered by the shared node 330 of the inductor unit 30 and the power voltage V1. The voltage control unit 60 has a plurality of inverters or buffers 610, 620 . . . 630, corresponding to voltage control signals VC1, VC2 . . . VCN, for inverting signal phase of the voltage control signals VC1, VC2 . . . VCN. The inverting control signals VC1, VC2 . . . VCN are coupled to the bias points 414, 424 . . . 434 of the switch capacitor sets SW1, SW2 . . . SWN to control over the switch capacitor sets, respectively. The voltage control unit 60 is powered by the shared node 330 and the power voltage V1 such that the inverters 610, 620 . . . 630 are also powered by the shared node 330 and the power voltage V1.

Different operating frequency requires different capacitance value controlled by the ON/OFF status of the varactors of the capacitor sets SW1, SW2 . . . SWN. According to the present invention, when a varactor is OFF, the potentials at two ends of the varactor is about the same, which increase tuning range between the ON capacitance C_{ON} and OFF capacitance C_{OFF}. In addition, the inverters 610, 620 . . . 630 are all coupled and powered by the shared node 330 of the inductor unit 30 such that flicker noise from the oscillator outputs VCOP and VCON are about the same so as to eliminate phase noise.

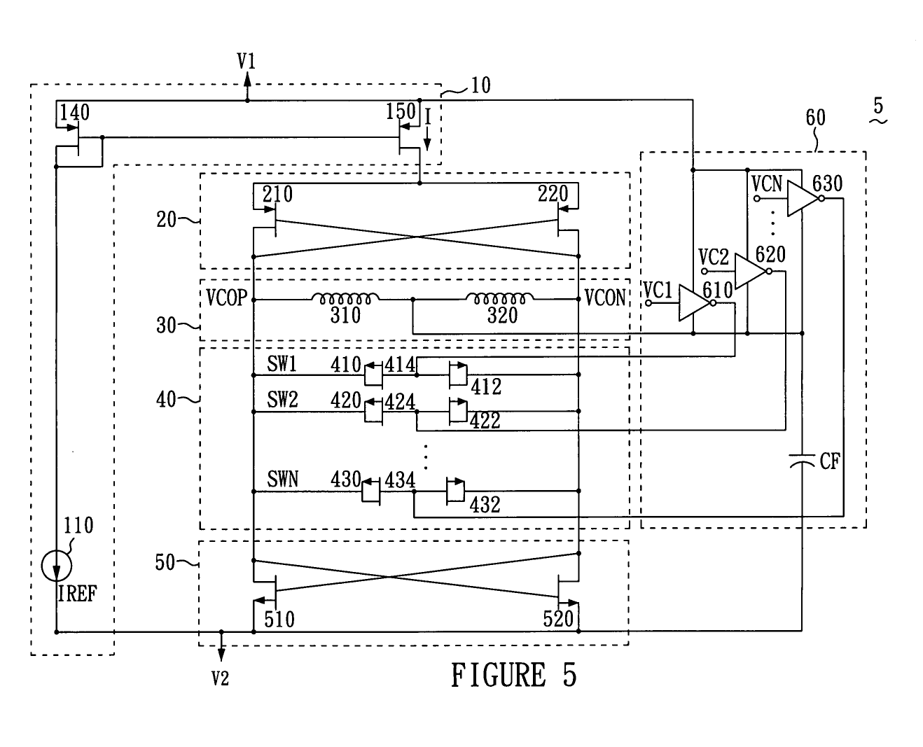

FIG. 5 shows a still another preferred embodiment of a voltage controlled oscillator 5 of the present invention. As compared with the embodiment shown in FIG. 4, in FIG. 5, a voltage controlled oscillator 5 further includes a capacitor CF between the shared node 330 of the inductor unit 30 and the power voltage V2. The signals going through the oscillator outputs VCOP and VCON are differential signals, which generates 2^{nd} harmonic at the shared node 330 of the inductor unit 30. According to the present invention, the capacitor CF installed and the inductor unit 30 form a low pass filter for filtering the 2nd harmonic.

The above disclosed subject matter is to be considered illustrative and the appended claims are intended to cover all such modifications and other embodiments which fall within the true spirit and scope of the present invention. Thus, to the maximum extent allowed by law, the scope of the present invention is to be determined by the broadest possible interpretation of the following claims and their equivalents, and shall not be restricted or limited by the foregoing detailed description.

What is claimed is:

1. A CMOS cross-coupled differential voltage controlled oscillator provided with a pair of oscillator outputs, comprising:
a current control unit coupled between a relatively-high voltage and a relatively-low voltage;
a first cross-coupled differential pair, an inductor unit, a capacitor unit and a second cross-coupled differential pair are coupled between said pair of oscillator outputs in parallel and cascaded between said current control unit and said relatively-high voltage, wherein said inductor unit includes a shared node; and
a voltage control unit coupled between said shared node and said relatively-low voltage, wherein said voltage control unit controls said capacitor unit according to a plurality of voltage control signals and then outputs signals to said pair of oscillator outputs.

2. The CMOS cross-coupled differential voltage controlled oscillator of claim 1, wherein said inductor unit has a first inductor and a second inductor serially coupled between said pair of oscillator outputs and a coupling node of said first inductor and said second inductor is said shared node.

3. The CMOS cross-coupled differential voltage controlled oscillator of claim 1, wherein said inductor unit is a single inductor and the location near the middle of said single inductor is said shared node.

4. The CMOS cross-coupled differential voltage controlled oscillator of claim 1, wherein said capacitor unit has a plurality of switch capacitor sets coupled between said pair of oscillator outputs in parallel.

5. The CMOS cross-coupled differential voltage controlled oscillator of claim 4, wherein each said switch capacitor set has a first capacitor and a second capacitor serially coupled between said pair of oscillator outputs, a coupling node of said first capacitor and said second capacitor is a bias point.

6. The CMOS cross-coupled differential voltage controlled oscillator of claim 5, wherein said voltage control unit has a plurality of buffers for coupling said voltage control signals to said bias points of said switch capacitor sets, respectively.

7. The CMOS cross-coupled differential voltage controlled oscillator of claim 1, wherein said first cross-coupled differential pair is a pair of cross-coupled PMOS field effect transistors.

8. The CMOS cross-coupled differential voltage controlled oscillator of claim 1, wherein said second cross-coupled differential pair is a pair of cross-coupled NMOS field effect transistors.

9. The CMOS cross-coupled differential voltage controlled oscillator of claim 1, further comprises a capacitor coupled between said shared node and said relatively-low voltage.

10. A CMOS cross-coupled differential voltage controlled oscillator having a pair of oscillator outputs, comprising:
a current control unit coupled between a relatively-high voltage and a relatively-low voltage;
a first cross-coupled differential pair, an inductor unit, a capacitor unit and a second cross-coupled differential pair are coupled between said pair of oscillator outputs and cascaded between said current control unit and said relatively-low voltage, wherein said inductor unit includes a shared node; and
a voltage control unit coupled between said shared node and said relatively-high voltage, wherein said voltage control unit controls said capacitor unit according to a plurality of voltage control signals and then outputs signals to said pair of oscillator outputs.

11. The CMOS cross-coupled differential voltage controlled oscillator of claim 10, wherein said inductor unit has a first inductor and second inductor serially coupled between said pair of oscillator outputs and a coupling node of said first inductor and said second inductor is said shared node.

12. The CMOS cross-coupled differential voltage controlled oscillator of claim 10, wherein said inductor unit is a single inductor and the location near the middle of said single inductor is said shared node.

13. The CMOS cross-coupled differential voltage controlled oscillator of claim 10, wherein said capacitor unit has a plurality of switch capacitor sets coupled between said pair of oscillator outputs in parallel.

14. The CMOS cross-coupled differential voltage controlled oscillator of claim 13, wherein each said switch capacitor set has a first capacitor and second capacitor serially coupled between said pair of oscillator outputs, a coupling node of said first capacitor and said second capacitor is a bias point.

15. The CMOS cross-coupled differential voltage controlled oscillator of claim 14, wherein said voltage control unit has a plurality of buffers for coupling said voltage control signals to said bias points of said switch capacitor sets, respectively.

16. The CMOS cross-coupled differential voltage controlled oscillator of claim 10, wherein said first cross-coupled differential pair is a pair of cross-coupled PMOS field effect transistors.

17. The CMOS cross-coupled differential voltage controlled oscillator of claim 10, wherein said second cross-coupled differential pair is a par of cross-coupled NMOS field effect transistors.

18. The CMOS cross-coupled differential voltage controlled oscillator of claim 10, further comprises a capacitor coupled between said shared node and said relatively-low voltage.
